(19) United States
(12) Patent Application Publication
(10) Pub. No.: US 2007/0273011 A1
(43) Pub. Date: Nov. 29, 2007

(54) METHOD FOR FABRICATING A MODULE HAVING AN ELECTRICAL CONTACT-CONNECTION

(75) Inventors: Laurence Edward Singleton, Dresden (DE); Harry Hedler, Germering (DE); Roland Irsigler, Muenchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/752,575

(22) Filed: May 23, 2007

(30) Foreign Application Priority Data
May 23, 2006 (DE) 10 2006 024 213

(51) Int. Cl. H01L 23/495; H01L 21/44; H01L 21/00

(52) U.S. Cl. 257/673; 438/612; 438/106

(57) ABSTRACT

A method for fabricating a module having an electrical contact-connection is disclosed. One embodiment provides a chip having a contact area, applying a contact elevation to the contact area and applying a solder material to the contact elevation. The contact elevation may be applied to the contact area by using a bonding process in order to implement the contact elevation in the form of a stud bump.

### CROSS-REFERENCE TO RELATED APPLICATIONS

This Utility Patent Application claims priority to German Patent Application No. DE 10 2006 024 213.0 filed on May 23, 2006, which is incorporated herein by reference.

### BACKGROUND

Embodiments described below relate to a method for fabricating a module having an electrical contact-connection which in one embodiment is used to electrically connect the module to a contact position on a printed circuit board.

When constructing electronic modules, chips, that is to say the bare silicon laminas (bare dice), are connected to a carrier substrate in such a manner that the chips are securely held on the carrier substrate and are electrically connected to contact regions on the carrier substrate in a suitable manner. Provision may be made to provide the contact regions on the carrier substrate with a solder material, contact elevations which are provided in contact areas of the chip then being placed onto the contact regions. As a result of a subsequent heat treatment process, the solder material melts and the contact elevation is mechanically and electrically connected to the respective contact region on the carrier substrate.

The operation of applying the solder material to the contact regions is a relatively complicated process in which, for example, the solder material is applied to the contact regions of the carrier substrate in the form of a solder paste with the aid of a stencil printing method, a heat treatment process is then carried out and the flux contained in the solder material is subsequently removed with the aid of a cleaning process. The high level of complexity involved in fabricating such substrates renders the latter expensive, and it is desirable to provide a method for fabricating an electronic module which manages with more reasonable carrier substrates.

For these and other reasons, there is a need for the present invention.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIGS. 1a to 1d illustrate method processes for fabricating a chip having contact elevations.

FIGS. 2a to 2d illustrate further method processes for fabricating a chip.

FIGS. 3a to 3d illustrate further method processes for fabricating a chip.

FIG. 4 illustrates an electronic module including a chip having contact elevations.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

One or more embodiments relate to a method for fabricating a chip which is to be used to fabricate an electronic module and to a method for fabricating an electronic module that may resort to simple carrier substrates which are fabricated in a less complicated manner.

One embodiment relates to a method for fabricating a chip used to construct an electronic module. The method includes the processes of providing a chip having a contact area, applying a contact elevation to the contact area and applying a solder material to the contact elevation. The contact elevation may be implemented in the form of a stud bump, with a material including e.g., gold.

The method provides for fabricating a chip having a contact elevation on which a solder material is situated. As a result, the chip may be connected to contact regions on a substrate which do not have any solder material. Such contact regions may be situated, for example, on carrier substrates for fabricating modules, in which case such carrier substrates may be fabricated in a less complicated manner and, as a result, are more cost-effective if the contact regions on them are not provided with a solder material.

To fabricate an electronic module, a chip having a contact elevation that is provided with the solder material is fabricated and the chip is then applied to a provided carrier substrate by the contact elevation being placed onto a contact region of the carrier substrate and the solder material being fused to the contact elevation in a heat treatment process so that the contact elevation combines with the contact region of the carrier substrate via the solder material.

The solder material may be applied by immersing the contact elevation in a bath including liquid solder material.

The solder material may be applied to the contact elevation by using a stencil printing method. For this purpose, a stencil having a passage hole is placed onto the module at the position of the contact elevation and a solder paste is then introduced into the passage hole with the solder material so that the solder paste comes into contact with the contact elevation. A heat treatment process may be carried out after the solder paste has been introduced in order to melt the solder paste so that the solder material combines with the material of the contact elevation, and the stencil is then removed. The stencil may be removed as soon as the solder paste has been introduced and a heat treatment process may then be carried out in order to melt the solder paste so that the solder material combines with the material of the contact elevation.

Provision may be made of a flat template having a depression into which a solder paste is introduced with the solder material. A heat treatment process may then be carried out in order to melt the solder paste, the module being placed onto the flat template in such a manner that the contact elevation projects into the depression so that the material of the contact elevation combines with the molten solder material.

According to another embodiment, a module is produced according to one of the methods described above.

Another embodiment relates to a chip having an electrical contact-connection, in which the electrical contact-connection has a contact elevation that is applied to a contact area, a solder material being applied to the contact elevation. Another embodiment provides such a chip for fabricating an electronic module.

Further exemplary embodiments are explained in conjunction with the drawings.

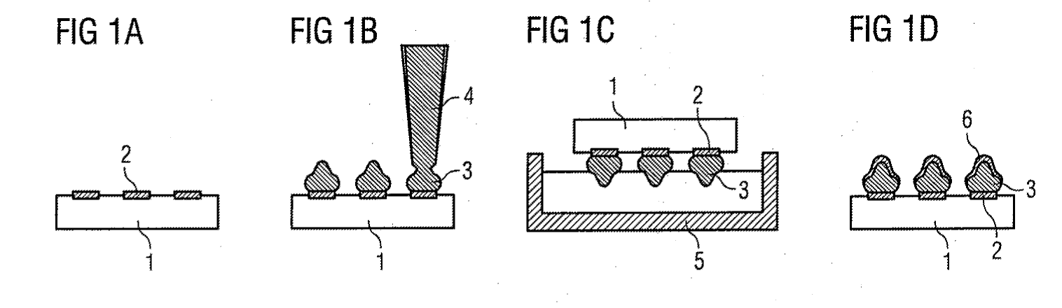

FIGS. 1a to 1d illustrate method processes for fabricating a chip 1, for example a silicon chip. The method process illustrated in FIG. 1a illustrates a chip 1 having contact areas 2 which are applied to the latter and may be used to contact-connect structures, for example electronic circuits, on the chip 1 from the outside. The contact areas 2 are provided with a metallic material including, for example, aluminum or similar materials which are used when fabricating electronic integrated circuits.

In a subsequent method process which is illustrated in FIG. 1b, contact elevations 3 are applied to the contact areas 2, the contact elevations projecting above that surface of the chip 1 on which the contact areas 2 are situated and being used to provide a contact-connection to the electronic circuits in the chip. The contact elevations 3 may be in the form of stud bumps which are applied using a bonding process with the aid of a bonding device 4. The material of the stud bumps 3 may e.g., be gold which is suitable for combining with the contact area 2 by being pressed onto the contact areas 2 and for providing a mechanically stable and electrically highly conductive connection. The stud bumps 3 are formed by the bonding device 4 pressing a gold wire onto the contact area 2 and by the gold wire being cut immediately after the bead which forms in this manner and is securely connected to the contact areas 2, with the result that the stud bump remains on the contact area 2 as a contact elevation 3 without a protruding gold wire. The contact elevations 3 may also be fabricated using another method.

In order to implement an electrical contact-connection using these stud bumps 3, the stud bumps 3, for their part, need to be able to be mechanically and electrically connected to further contact regions. Since the melting point of the material of the stud bumps 3, in this case gold, is too high to avoid the electronic structures on the chip 1 being damaged during their fusing, the stud bumps 3 must be contact-connected to contact regions with the aid of a further auxiliary material which may be a solder material. Whereas this solder material may usually be provided in the contact regions which may be situated, for example, on the carrier substrate for constructing an electronic module, the contact elevations are immersed in a solder bath 5 in a subsequent method process which is illustrated in FIG. 1c, with the result that the stud bumps 3 are wetted with the molten solder in the solder bath 5 and, on account of adhesion forces, a particular quantity of the solder adheres to the stud bumps 3 as a solder cover 6 after the method process (illustrated in FIG. 1d) of removing the contact elevations 3 from the solder bath 5. This makes it possible to provide a chip 1 having contact elevations which are provided with a solder cover 6, with the result that the chip 1 is suitable for being placed onto contact regions on a substrate and being soldered to the contact regions without the contact regions themselves having to have a solder material.

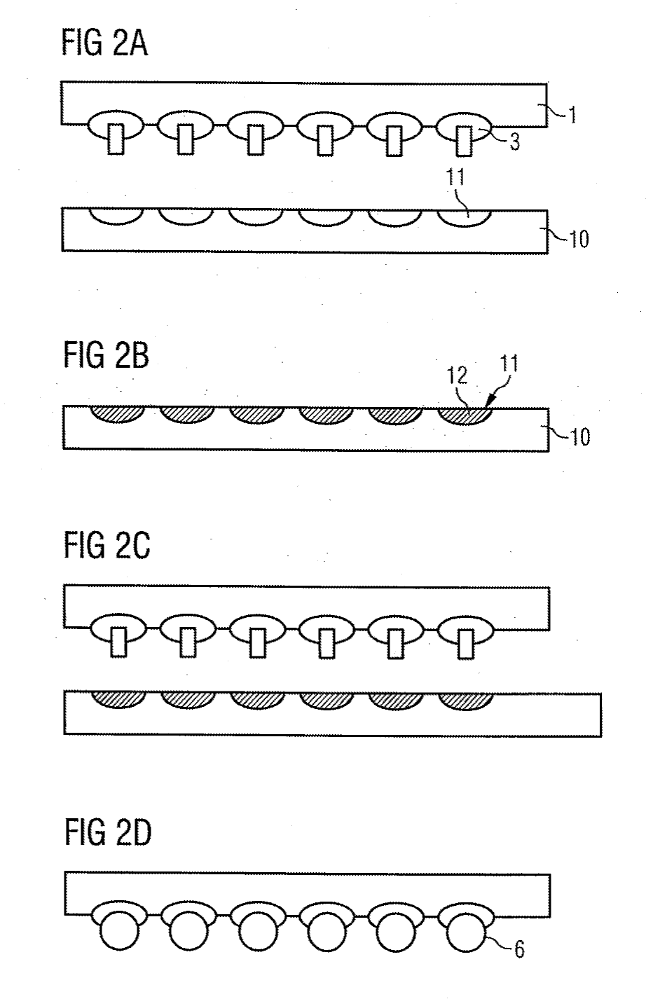

FIGS. 2a to 2d illustrate a further method for fabricating a chip using the method processes illustrated in FIGS. 2a to 2d. As illustrated in the method process illustrated in FIG. 2a, a stencil 10 having depressions 11 is provided, the depressions 11 being arranged on the stencil 10 in such a manner that the chip 1 which may be fabricated in the same manner as illustrated by the method processes illustrated in FIGS. 1a and 1b may be placed onto the stencil headfirst, so that the stud bumps 3 may respectively project into an assigned depression 11. The depressions 11 for receiving the stud bumps 3 on the chip 1 are basically arranged in a mirror-inverted manner to the arrangement of the stud bumps 3 on the chip 1.

According to the method process illustrated in FIG. 2b, the depressions 11 are filled with a solder paste 12 by the solder paste being extensively applied to that surface of the stencil 10 which is provided with the depressions 11 and then being wiped off the surface with the aid of a scraper, for example, with the result that the solder paste 12 only remains in the depressions 11.

As illustrated in FIG. 2c, the stencil 10 and the chip 1 with the stud bumps 3 are then aligned with respect to one another and the stencil 10 having the depressions 11 which are respectively filled with solder paste is heated so that the solder paste melts. Before the process of melting the solder paste 12 or after the process, the stud bumps 3 of the chip 1 are immersed in the depressions 11 so that the solder material combines with the gold material of the stud bumps 3 and the contact elevations with the solder covers 6 illustrated in FIG. 2d are thus formed.

Instead of the heat treatment process for melting the solder paste in the depressions 11, the solder paste 12 may also be provided with a self-curing material so that, after the stud bumps 3 have been immersed in the depressions 11 and in the solder paste 12 situated in the latter, the solder paste cures and adheres to the stud bumps 3. The stud bumps 3 may likewise be provided with the solder covers 6 in this manner, the solder covers 6 including a solidified solder paste material rather than a molten solder material.

Depending on the ability of the solder paste material to adhere to the stud bumps 3 even without being melted, the stud bumps 3 may also be lifted out of the depressions again after the method process illustrated in FIG. 2c, the solder paste material adhering to the stud bumps 3, and a heat treatment process which is used to melt the solder paste material which adheres to the stud bumps 3 may then be carried out, and the solder paste material combines with the material of the stud bumps in this manner. This makes it possible to avoid the stencil 10 being heated, thus extending the service life of the stencil 10.

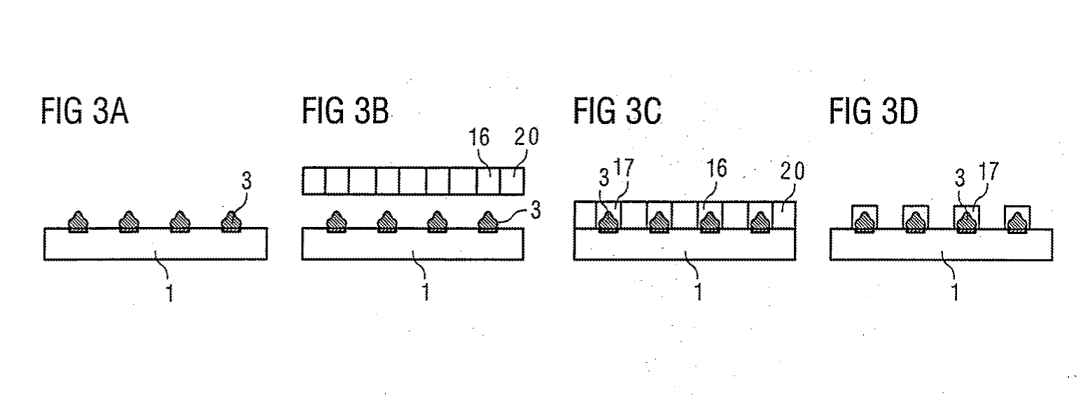

As illustrated in the following FIGS. 3a to 3d, a further stencil 20 may also be provided with passage holes 16 at the positions of the contact elevations 3 and may be placed onto the chip 1. The solder paste material 17 is then introduced into the passage openings 16 from the side opposite the chip 1 and the further stencil 20 is removed before or after melting the solder paste or before or after curing the solder paste, with the result that the contact elevations 3 are provided with solder material.

The result of the above-described different methods for fabricating a chip 1 which may be used to construct an electronic module is a chip 1 having contact elevations 3 which each have a solder cover 6, with the result that the chip 1 may be applied to contact regions which have not been provided with a solder by using a fusing process. As a result, the chip 1 becomes suitable for being connected to a carrier substrate for constructing an electronic module, for example a ball grid array (BGA) module, without having to provide a carrier substrate having contact regions which are provided with a solder material. This makes it possible to use carrier substrates whose contact regions do not have to be provided with a solder material.

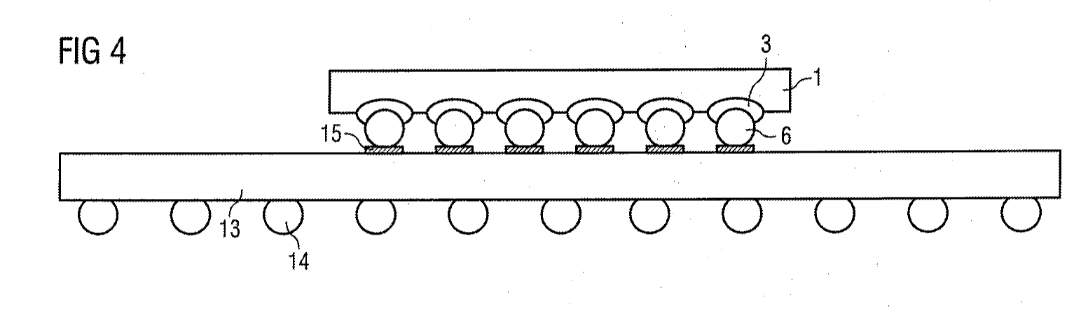

FIG. 4 illustrates an exemplary module which has been fabricated in this manner. The module includes a carrier substrate 13 which has, on a first surface, contact elements 14 in the form of solder balls for contact-connecting the module from the outside. The contact elements 14 are electrically connected to contact regions 15 on an opposite, second surface of the carrier substrate 13 in a suitable manner using a rewiring structure (not shown) which is provided in the carrier substrate 14. The contact regions 15 are metallic areas which are not provided with a solder and may combine with the solder material of the solder covers 6 of the associated stud bumps 3 in a heat treatment process.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for fabricating an electronic module comprising:
providing a chip having a contact area;
applying a contact elevation to the contact area, wherein the contact elevation is applied using a bonding process, configured to implement the contact elevation as a stud bump; and
applying a solder material to the contact elevation, to form an electrical contact-connection.

2. The method of claim 1, coupling the chip to a carrier substrate.

3. The method of claim 1, comprising applying the solder material to the contact elevation by immersing the contact elevation in a bath comprising liquid solder material.

4. The method of claim 1, comprising applying the solder material to the contact elevation by using a stencil printing method.

5. The method of claim 4, comprising placing a stencil having a passage hole onto the chip at the position of the contact elevation and introducing a solder paste into the passage hole with the solder material causing the solder paste to come into contact with the contact elevation.

6. The method of claim 5, comprising carrying out a heat treatment process out after introducing the solder paste into the passage hole in order to melt the solder paste, causing the solder material to combine with the material of the contact elevation, and subsequently the stencil is removed.

7. The method of claim 5, comprising removing the stencil after introducing the solder paste into the passage hole, and carrying out a heat treatment process out in order to melt the solder paste, thereby causing the solder material to combine with the material of the contact elevation.

8. A method for fabricating a chip having an electrical contact-connection, comprising:
providing a chip having a contact area;
applying a contact elevation to the contact area, wherein the contact elevation is applied by using a bonding process in order to implement the contact elevation in the form of a stud bump; and
applying a solder material to the contact elevation.

9. The method of claim 8, comprising using gold as material for the contact elevation.

10. The method of claim 8, comprising applying the solder material to the contact elevation by immersing the contact elevation in a bath comprising liquid solder material.

11. The method of claim 8, comprising applying the solder material to the contact elevation by using a stencil printing method.

12. The method of claim 11, comprising placing a stencil having a passage hole onto the chip at the position of the contact elevation and introducing a solder paste into the passage hole with the solder material causing the solder paste to come into contact with the contact elevation.

13. The method of claim 12, comprising carrying out a heat treatment process out after introducing the solder paste into the passage hole in order to melt the solder paste, thereby causing the solder material to combine with the material of the contact elevation, and subsequently the stencil is removed.

14. The method of claim 12, comprising removing wherein the stencil after introducing the solder paste into the passage hole, and carrying out a heat treatment process out in order to melt the solder paste, thereby causing the solder material to combine with the material of the contact elevation.

15. The method of claim 12, wherein the solder paste comprises a self-curing material.

16. The method of claim 8, comprising providing wherein a flat stencil having a depression into which a solder paste is introduced with the solder material, and wherein the chip is placed onto the flat stencil in such a manner that the contact elevation projects into the depression and the solder paste comes into contact with the contact elevation.

17. The method of claim 16, comprising carrying out wherein a heat treatment process out in order to melt the solder paste, thereby causing the solder material to combine with the material of the contact elevation, and subsequently removing the flat stencil.

18. The method of 16, comprising lifting the contact elevation out of the depression with the solder paste adhering to the contact elevation, and subsequently carrying out a heat treatment process in order to melt the solder paste, thereby causing the solder material to combine with the material of the contact elevation.

19. The method of claim 16, wherein the solder paste comprises a self-curing material.

20. A method for fabricating an electronic module, comprising:
providing a carrier substrate having a contact region;
providing a chip having a contact area;
applying a contact elevation to the contact area of the chip, wherein the contact elevation is applied by using a bonding process in order to implement the contact elevation in the form of a stud bump;
applying a solder material to the contact elevation of the chip;
placing the chip with the contact elevation onto the contact region of the carrier substrate; and
fusing the solder material of the contact elevation in a heat treatment process, thereby causing the contact elevation to combine with the contact region via the solder material.

21. A chip comprising:
an electrical contact-connection, wherein the electrical contact-connection comprises a contact elevation which is applied to a contact area by using a bonding process and which is implemented in the form of a stud bump, and wherein a solder material is applied to the contact elevation.

22. The chip of claim 21, wherein a material of the contact elevation comprises gold.

23. An electronic module comprising:
a chip having an electrical contact-connection, wherein the electrical contact-connection comprises a contact elevation which is applied to a contact area by using a bonding process and which is implemented in the form of a stud bump, and wherein a solder material is applied to the contact elevation; and
a carrier substrate coupled to the chip at the electrical contact-connection.
